(19) United States
(12) Patent Application Publication
(10) Pub. No.: US 2016/0351787 A1
(43) Pub. Date: Dec. 1, 2016

(54) ULTRASONIC SENSOR, METHOD FOR MANUFACTURING SAME AND ULTRASONIC SENSOR ARRAY

(71) Applicant: HON HAI PRECISION INDUSTRY CO., LTD., New Taipei (TW)

(72) Inventor: YI-CHENG LIN, New Taipei (TW)

(21) Appl. No.: 14/834,632

(22) Filed: Aug. 25, 2015

(30) Foreign Application Priority Data
May 30, 2015 (CN) 201510292195.6

(51) Int. Cl. H01L 41/113; H01L 41/316

(52) U.S. Cl. CPC H01L 41/1132; H01L 41/316

(57) ABSTRACT

An ultrasonic sensor can include a substrate, a first electrode, a sensing layer and a second electrode. The first electrode is coupled on the substrate. The sensing layer is coupled on the first electrode. The sensing layer has piezoelectric properties. The second electrode is coupled on the sensing layer. The second electrode has an electric conduction circuit formed thereon. A method for manufacturing the ultrasonic sensor is also provided. An ultrasonic sensor array is also provided.

### FIELD

The subject matter herein generally relates to sensor technology, and particularly to an ultrasonic sensor, a method for manufacturing the ultrasonic sensor and an ultrasonic sensor array.

### BACKGROUND

Ultrasonic sensors are used to determine positions, velocities, or other physical quantities of objects by transmitting and receiving ultrasonic signals. The ultrasonic sensor is widely used in vehicles, such as a reverse object detection system or a collision detection system detecting surrounding vehicles.

### BRIEF DESCRIPTION OF THE DRAWINGS

Implementations of the present technology will now be described, by way of example only, with reference to the attached figures.

FIG. 1 is a cross sectional view of an ultrasonic sensor in accordance with an embodiment of the present disclosure.

FIG. 2 is a flowchart of a method for manufacturing the ultrasonic sensor in FIG. 1.

FIG. 3 is cross sectional view of a base substrate.

FIG. 4 shows a first electrode formed on the base substrate in FIG. 3.

FIG. 5 shows a sensing layer formed on the first electrode in FIG. 4.

FIG. 6 shows a second electrode formed on the sensing layer.

FIG. 7 is a cross sectional view of an ultrasonic sensor array of a first embodiment.

FIG. 8 is a cross sectional view of an ultrasonic sensor array of a second embodiment.

FIG. 9 is a cross sectional view of an ultrasonic sensor array of a third embodiment.

FIG. 10 is a cross sectional view of an ultrasonic sensor array of a fourth embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

The present disclosure is described in relation to an ultrasonic sensor. The ultrasonic sensor can include a substrate, a first electrode, a sensing layer and a second electrode. The first electrode is coupled on the substrate. The sensing layer is coupled on the first electrode. The sensing layer has piezoelectric properties. The second electrode is coupled on the sensing layer. The second electrode has an electric conduction circuit formed thereon.

The present disclosure is described further in relation to a method for manufacturing an ultrasonic sensor. The method can include followings. A base substrate is provided. A first electrode is formed on the base substrate by physical vapor deposition (PVD) method. A sensing layer is formed on the first electrode by PVD method. A second electrode is formed on the sensing layer by PVD method.

The present disclosure is described further in relation to an ultrasonic sensor array. The ultrasonic sensor array can include a base and a plurality of ultrasonic sensors arranged on the base. Each of the ultrasonic sensors has piezoelectric properties. The plurality of ultrasonic sensors are configured to transmit and receive ultrasonic signals.

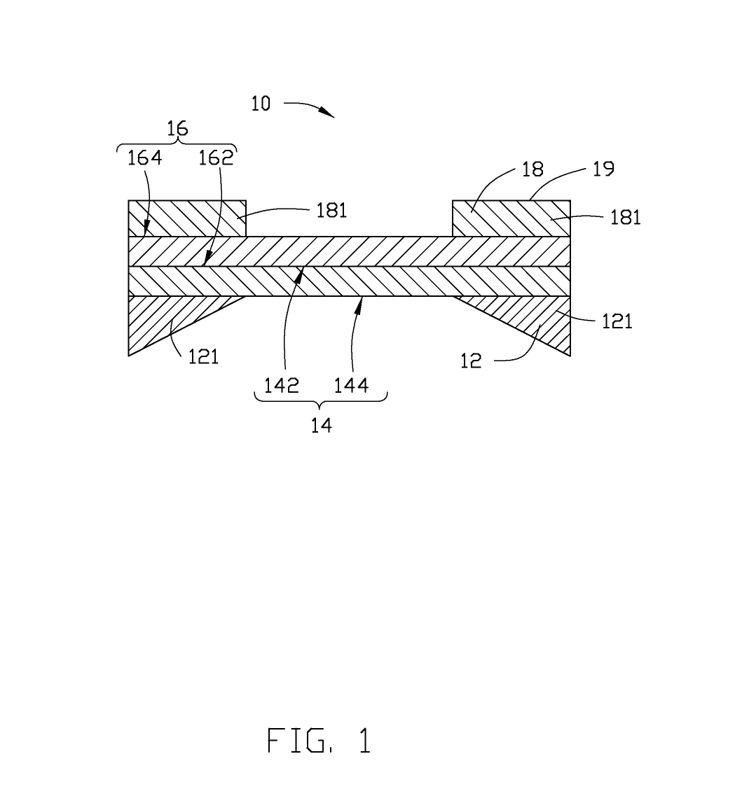

FIG. 1 illustrates that an ultrasonic sensor 10 can include a substrate 12, a first electrode 14 coupled on the substrate 12, a sensing layer 16 coupled on the first electrode 14 and a second electrode 18 coupled on the sensing layer 16.

The substrate 12 can include two spaced substrate portions 121. The two substrate portions 121 are symmetric to each other about an axis of the ultrasonic sensor 10. In at least one embodiment, each substrate portion 121 can be in a shape of right triangle. The substrate 12 is made of material of silicon.

The first electrode 14 can include a first face 142 and a second face 144 opposite to the first face 142. The first face 142 is coupled to the sensing layer 16. The second face 144 is coupled to the substrate 12. In at least one embodiment, the second face 144 is in direct physical contact with the two substrate portions 121.

The sensing layer 16 is formed on the first face 142 of the first electrode 14. The sensing layer 16 has piezoelectric properties. The sensing layer 16 includes a first face 162 and a second face 164 opposite to the first face 162. The first face 162 is coupled to the first face 142 of the first electrode 14. In at least one embodiment, the first face 162 is in direct physical contact with the first face 142 of the first electrode 14. A material of the sensing layer 16 can be piezoelectric polymers such as Polyvinylidene fluoride (PVDF).

The second electrode 18 is formed on the second face 164 of the sensing layer 16. The second electrode 18 can include two spaced electrode portions 181. The two electrode portions 181 are corresponding to the two substrate portions 121. The second electrode 18 has an electric conduction circuit 19 formed thereon.

The ultrasonic sensor 10 is configured to transmit and/or receive ultrasonic signals. When the ultrasonic sensor 10 produces inverse piezoelectric effect, the ultrasonic sensor 10 transmits ultrasonic signals. The inverse piezoelectric effect is that the sensing layer 16 transmits ultrasonic signals when the sensing layer 16 is applied voltage signal to vibrate. When the ultrasonic sensor 10 produces piezoelectric effect, the ultrasonic sensor 10 receives the ultrasonic signals. The piezoelectric effect is that the sensing layer 16 gets voltage signal when the sensing layer 16 receives ultrasonic signals to vibrate.

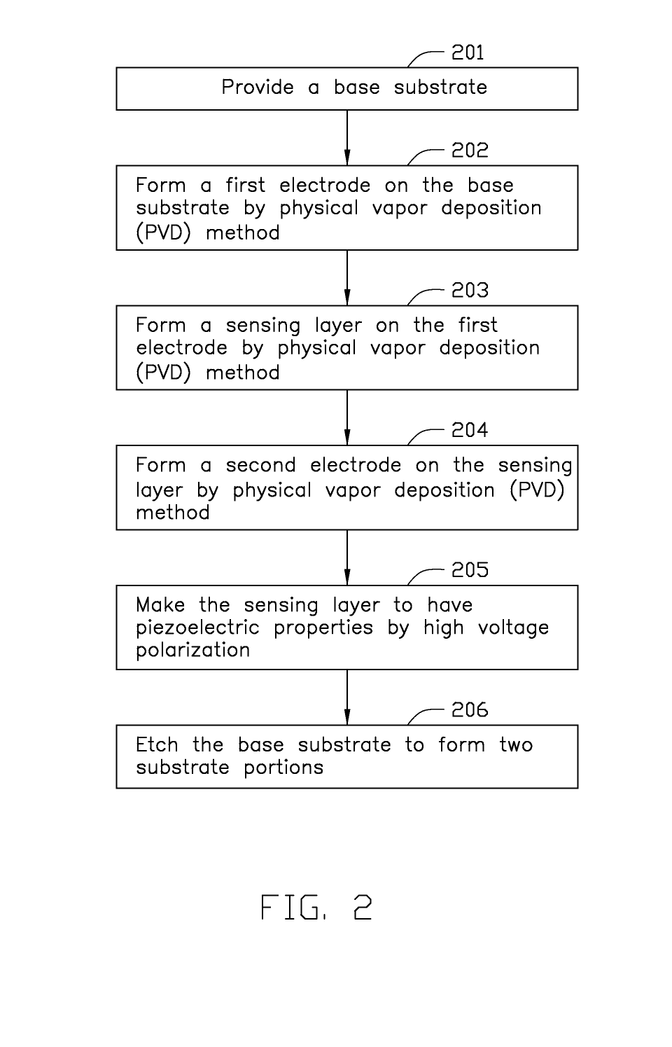

FIG. 2 illustrates a flowchart of an example method for manufacturing the ultrasonic sensor 10. The example method is provided by way of example, as there are a variety of ways to carry out the method. The example method described below can be carried out using the configurations illustrated in FIGS. 1 and 3-6, for example, and various elements of these figures are referenced in explaining the example method. Each block shown in FIG. 2 represents one or more processes, methods or subroutines, carried out in the example method. Furthermore, the illustrated order of blocks is illustrative only and the order of the blocks can change according to the present disclosure. Additional blocks can be added or fewer blocks may be utilized, without departing from this disclosure. The example method can begin at block 201.

In at least one embodiment, the ultrasonic sensor 10 can be made by method of manufacture procedure of Micro-electromechanical Systems (MEMS).

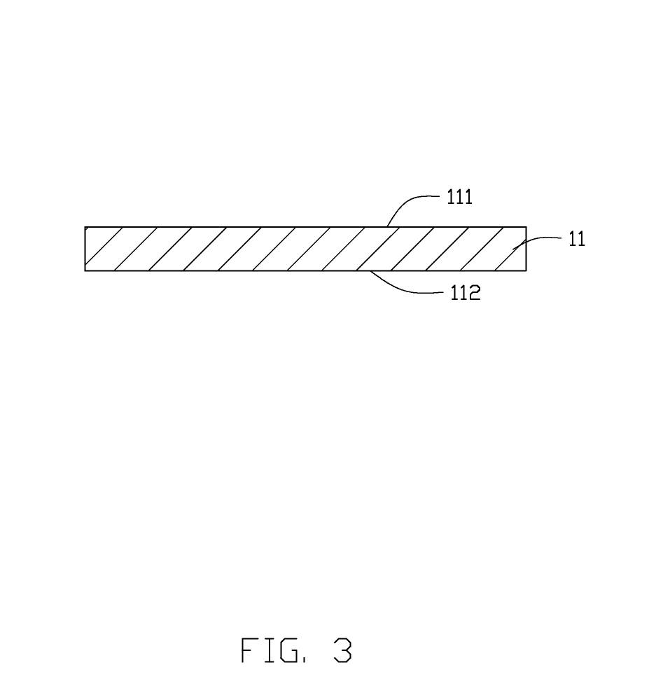

At block 201, also referring to FIG. 3, a base substrate 11 is provided. The base substrate 11 can be silicon. The base substrate 11 can have a rectangular cross section. The base substrate 11 has a top face 111 and a bottom face 112 opposite and parallel to the top face 111

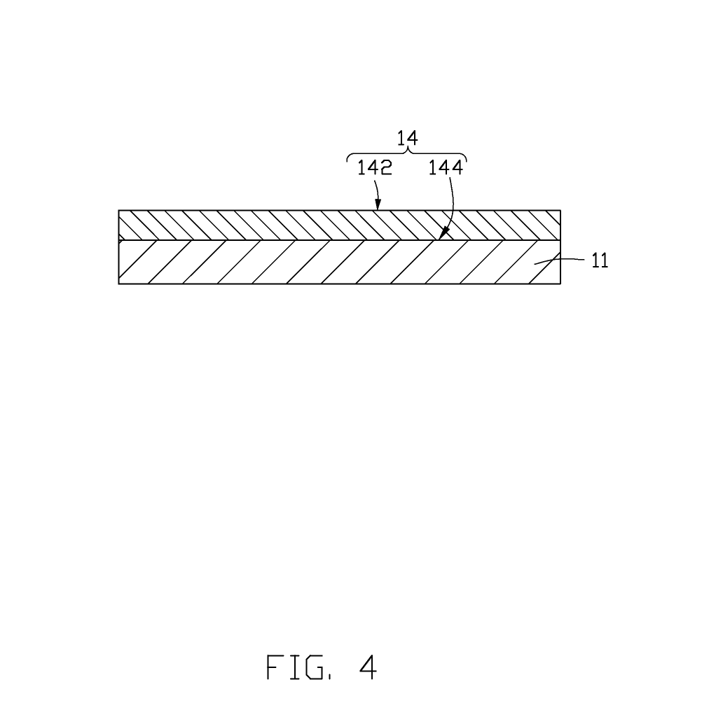

At block 202, also referring to FIG. 4, a first target substrate is provided, the first electrode 14 is formed on the base substrate 11 by PVD method. The first electrode 14 can include the first face 142 and the second face 144 opposite to the first face 142. The second face 144 is coupled on the top face 111 of the base substrate 11. In at least one embodiment, the second face 144 is in direct physical contact with the top face 111 of the base substrate 11. The first electrode 14 can have a material that is the same as the first target substrate. The material of the first electrode 14 can be metal with high electric conduction, such as platinum, copper, aluminum, titanium or one of an alloy of one of these.

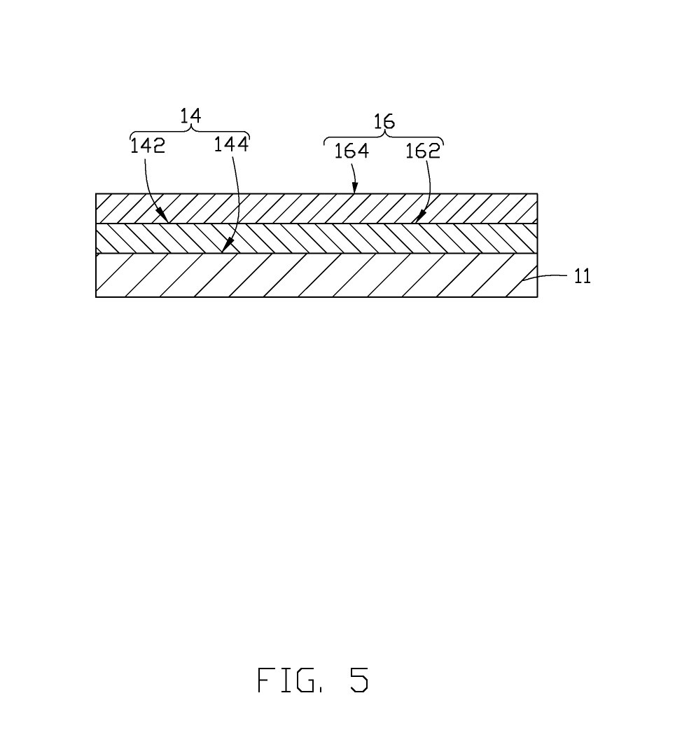

At block 203, also referring to FIG. 5, a second target substrate is provided, the sensing layer 16 is formed on the first electrode 14 by physical vapor deposition (PVD) method. The sensing layer 16 can include the first face 162 and the second face 164 opposite to the first face 162. In at least one embodiment, the first face 162 can be in direct physical contact with the first face 142 of the first electrode 14. The sensing layer 16 can have a material same as that of the second target substrate. The material of the sensing layer 16 can be material of piezoelectric polymers such as PVDF.

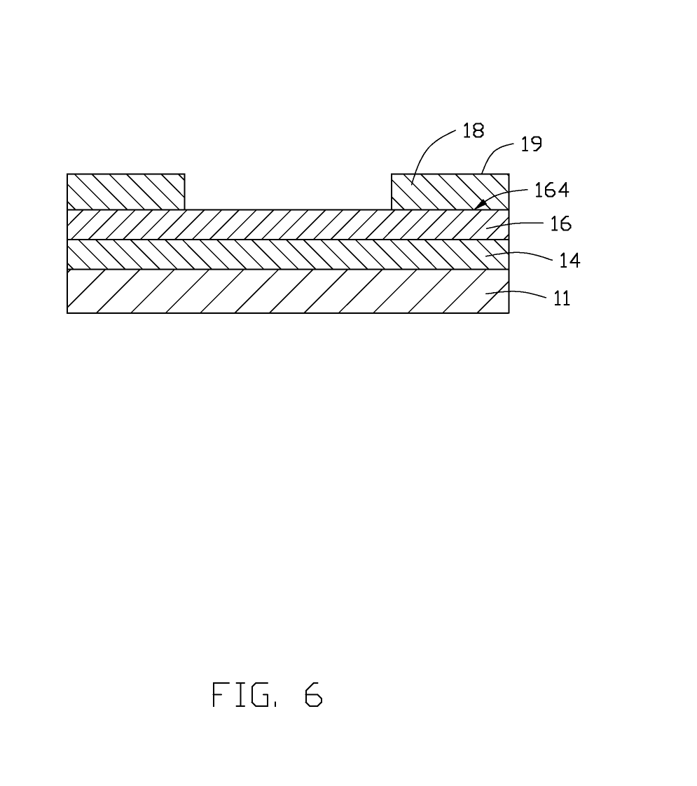

At block 204, also referring to FIG. 6, a third target substrate is provided, the second electrode 18 is formed on the sensing layer 16 by physical vapor deposition (PVD) method. The electric conduction circuit 19 is formed on the second electrode 18 by lithography way. The second electrode 18 can include the two spaced electrode portions 181. In at least one embodiment, the second electrode 18 can be in direct physical contact with the second face 164 of the sensing layer 16. The second electrode 18 can have a material same as that of the third target substrate. The material of the second electrode 18 can be can be metal with great electric conduction, such as platinum, copper, aluminum, titanium or its alloys.

At block 205, the sensing layer 16 is made to have piezoelectric properties by high voltage polarization, such that the sensing layer 16 can convert the voltage single to vibration signal, or convert the vibration signal to the voltage single. In at least one embodiment, block 205 can be before block 204.

At block 206, also referring to FIG. 1, the base substrate 11 is etched to form the substrate 12. The substrate 12 can include the two spaced substrate portions 121. The two spaced substrate portions 121 are corresponding to the two spaced electrode portions 181 of the second electrode 18.

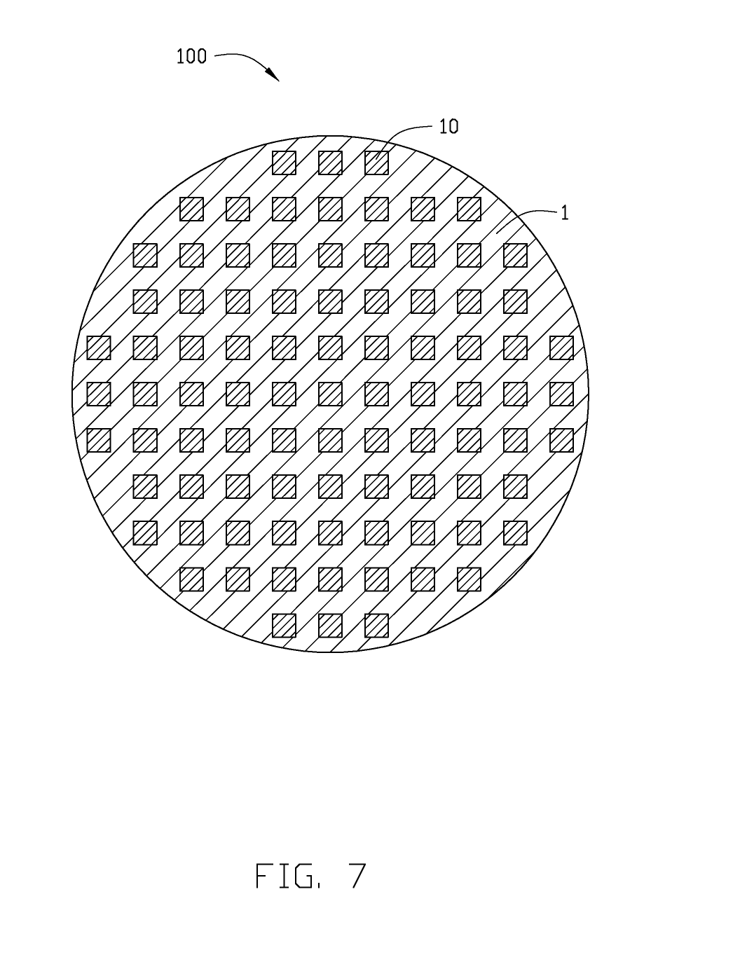

FIG. 7 illustrates an ultrasonic sensor array 100 of a first embodiment. The ultrasonic sensor array 100 includes a plurality of ultrasonic sensors 10 and a processor (not shown).

The plurality ultrasonic sensors 10 are arranged on a base 1. The base 1 can have a cross section in a circular shape. In at least one alternative embodiment, the base 1 can have a cross section in rectangular shape, square shape, ellipse shape or other shapes. Material of the base 1 can be silicon.

The plurality of ultrasonic sensors 10 are arranged in a matrix array on the base 1. The plurality of ultrasonic sensors 10 are arranged in a plurality of rows and columns. The plurality of rows can be spaced from each other. The plurality of columns can be spaced from each other. Distances between two adjacent rows are same to each other. Distances between two adjacent columns are same to each other. The ultrasonic sensors 10 in each row and column are arranged evenly and with a certain interval therebetween.

In this embodiment, each of the ultrasonic sensors 10 is configured to transmit and receive ultrasonic signals.

The ultrasonic sensor array 100 is configured to measure a distance of an object.

In use of the ultrasonic sensor array 100 to measure the distance between a sensed object and the ultrasonic sensor array 100, the ultrasonic sensors 10 transmit ultrasonic signals to the sensed object. When the ultrasonic signals reach the sensed object, the ultrasonic signals are reflected to the ultrasonic sensor array 100 and are received by the ultrasonic sensors 10. The processor calculates the distance between the sensed object and the ultrasonic sensor array 100 according to a time difference between transmitting the ultrasonic signals and receiving the ultrasonic signals by the ultrasonic sensors 10.

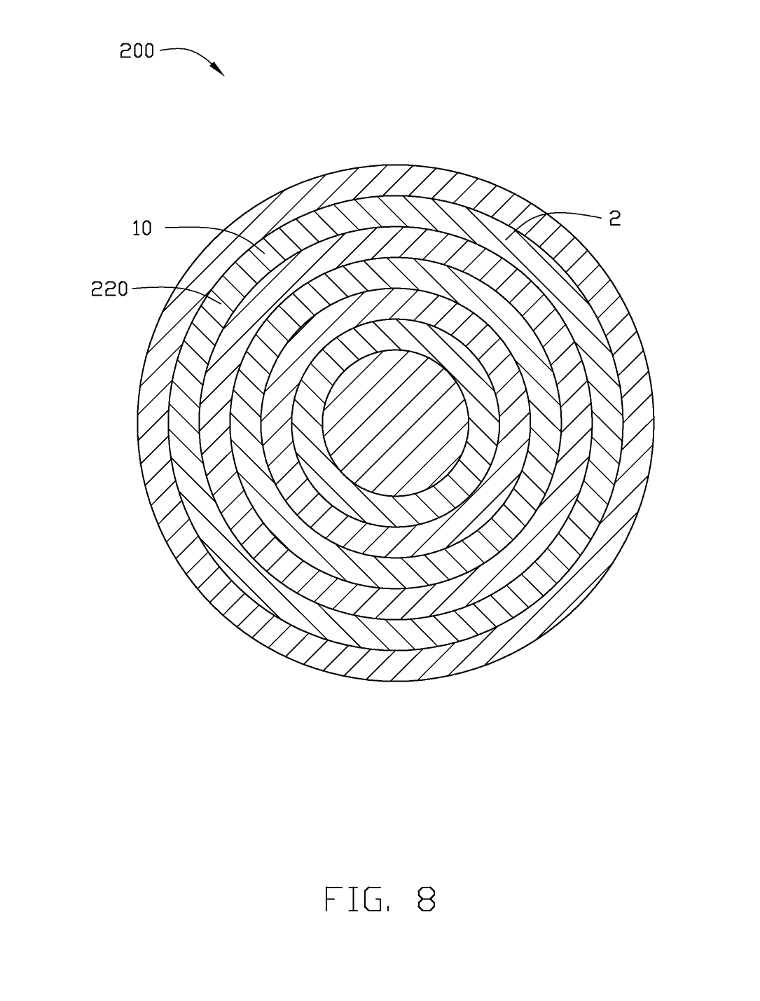

FIG. 8 illustrates an ultrasonic sensor array 200 of a second embodiment. The ultrasonic sensor array 200 includes a plurality of ultrasonic sensors 10 and a processor (not shown).

The plurality ultrasonic sensors 10 are arranged on a base 2. The base 2 can have a cross section in a circular shape. In at least one alternative embodiment, the base 2 can have a cross section in rectangular shape, square shape, ellipse shape or other shapes. Material of the base 2 can be silicon.

The plurality of ultrasonic sensors 10 are arranged on a plurality of concentric circles on the base 2. The concentric circles can be spaced from each other. The ultrasonic sensors 10 on each circle cooperatively form an ultrasonic sensor unit 220. Distances between two adjacent ultrasonic sensor units 220 along a radial direction are same to each other. In at least one embodiment, in each ultrasonic sensor unit 220, the ultrasonic sensors 10 can be coupled to each other. In at least one alternative embodiment, the ultrasonic sensors 10 in each ultrasonic sensor unit 220 are arranged evenly and with a certain interval therebetween.

In this embodiment, each of the ultrasonic sensors 10 is configured to transmit and receive ultrasonic signals.

The ultrasonic sensor array 200 is configured to measure a distance of an object.

In use of the ultrasonic sensor array 200 to measure the distance between a sensed object and the ultrasonic sensor array 200, the ultrasonic sensors 10 of the ultrasonic sensor units 220 transmit ultrasonic signals to the sensed object. When the ultrasonic signals reach the sensed object, the ultrasonic signals are reflected to the ultrasonic sensor array 200 and are received by the ultrasonic sensors 10. The processor calculates the distance between the sensed object and the ultrasonic sensor array 200 according to a time difference between transmitting the ultrasonic signals and receiving the ultrasonic signals by the ultrasonic sensors 10.

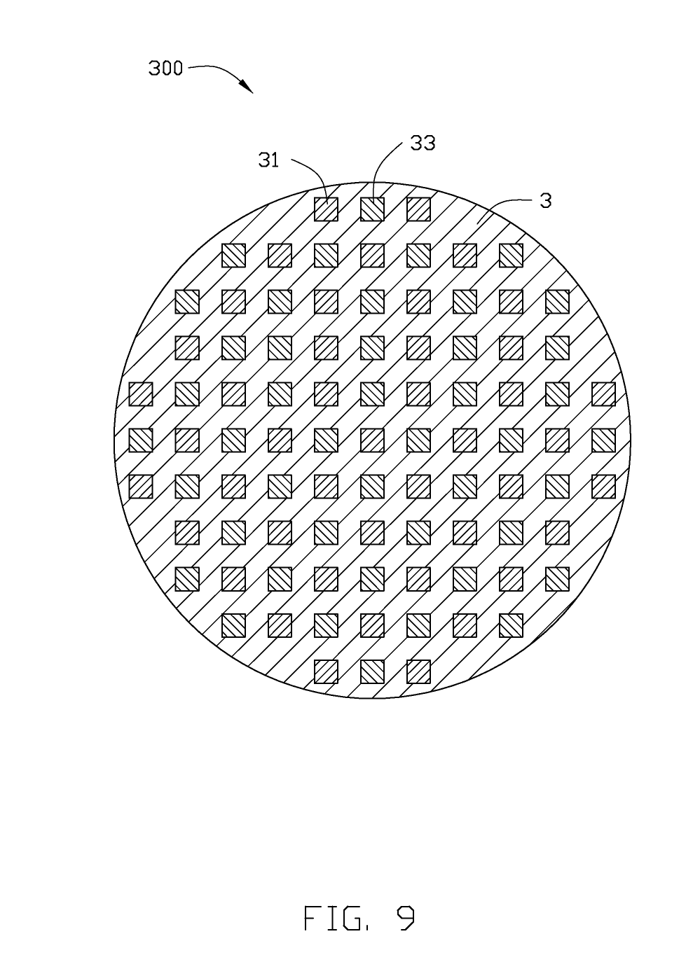

FIG. 9 illustrates an ultrasonic sensor array 300 of a third embodiment. The ultrasonic sensor array 300 includes a plurality of ultrasonic sensors 10 and a processor (not shown).

The plurality ultrasonic sensors 10 are arranged on a base 3. The base 3 can have a cross section in a circular shape. In at least one alternative embodiment, the base 3 can have a cross section in rectangular shape, square shape, ellipse shape or other shapes. Material of the base 3 can be silicon.

The plurality of ultrasonic sensors 10 are arranged in a matrix array on the base 3. The plurality of ultrasonic sensors 10 are arranged in a plurality of rows and columns. The plurality of rows can be spaced from each other. The plurality of columns can be spaced from each other. Distances between two adjacent rows are same to each other. Distances between two adjacent columns are same to each other. The ultrasonic sensors 10 in each row and column are arranged evenly and with a certain interval therebetween.

In this embodiment, the ultrasonic sensors 10 are divided to transmitters 31 and receivers 33 according to transmitting or receiving ultrasonic signals. The transmitter 31 is configured to transmit ultrasonic signals. The receiver 33 is configured to receive ultrasonic signals.

In each row and column on the base 3, the transmitters 31 and the receivers 33 are alternately arranged with each other.

The ultrasonic sensor array 300 is configured to measure a distance of an object from the ultrasonic sensor array 300.

In use of the ultrasonic sensor array 300 measuring the distance between a sensed object and the ultrasonic sensor array 300, the transmitters 31 transmit ultrasonic signals to the sensed object. When the ultrasonic signals reach the sensed object, the ultrasonic signals are reflected to the ultrasonic sensor array 300 and are received by the receivers 33. The processor calculates the distance between the sensed object and the ultrasonic sensor array 300 according to a time difference between transmitting the ultrasonic signals by the transmitters 31 and receiving the ultrasonic signals by the receivers 33.

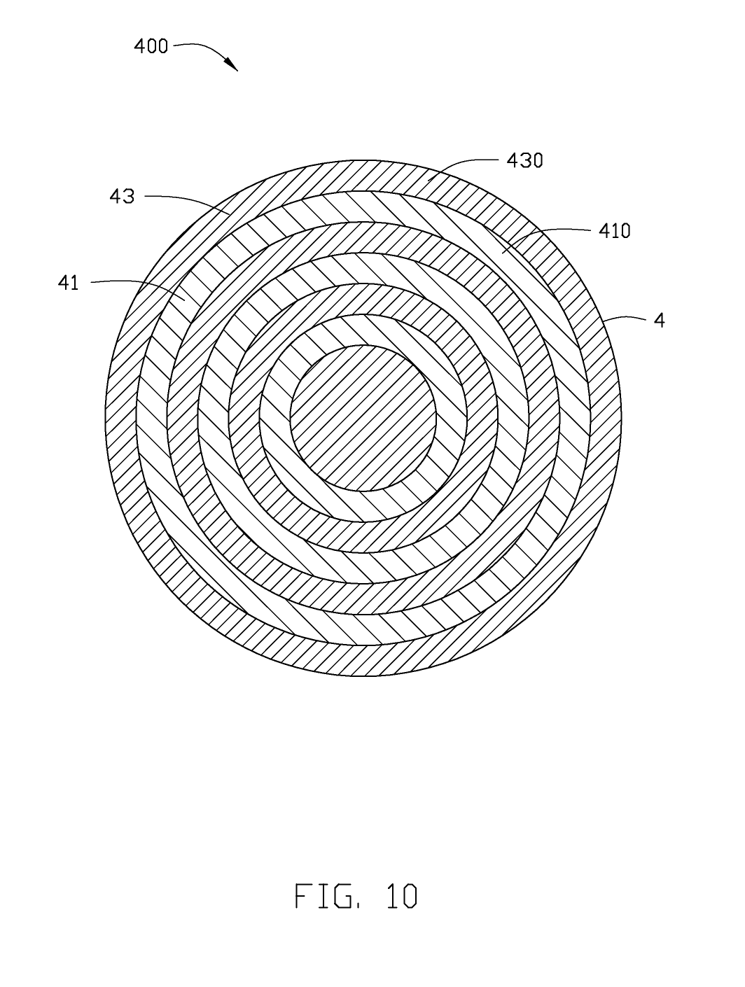

FIG. 10 illustrates an ultrasonic sensor array 400 of a fourth embodiment. The ultrasonic sensor array 400 includes a plurality of ultrasonic sensors 10 and a processor (not shown).

The plurality ultrasonic sensors 10 are arranged on a base 4. The base 4 can have a cross section in a circular shape. In at least one alternative embodiment, the base 4 can have a cross section in rectangular shape, square shape, ellipse shape or other shapes. Material of the base 4 can be silicon.

The plurality of ultrasonic sensors 10 are arranged on a plurality of concentric circles on the base 4. In this embodiment, the ultrasonic sensors 10 are divided to transmitters 41 and receivers 43 according to transmitting or receiving ultrasonic signals. The transmitter 41 is configured to transmit ultrasonic signals. The receiver 43 is configured to receive ultrasonic signals.

The transmitters 41 on a plurality of circles cooperatively form a plurality of transmitter units 410. The receivers 43 on a plurality of circles cooperatively form a plurality of receiver units 430. The transmitter units 410 and the receiver units 430 are alternately arranged with each other on the base 4. Distances between two adjacent transmitter units 410 and the receiver units 430 along a radial direction are same to each other. In at least one embodiment, in each transmitter unit 410, the transmitters 41 can be coupled to each other. In each receiver unit 430, the receivers 43 can be coupled to each other. In at least one alternative embodiment, the transmitters 41 in each transmitter unit 410 are arranged evenly and with a certain interval therebetween. The receivers 43 in each receiver unit 430 are arranged evenly and with a certain interval therebetween.

The ultrasonic sensor array 400 is configured to measure a distance of an object.

In use of the ultrasonic sensor array 400 measuring the distance between a sensed object and the ultrasonic sensor array 400, the transmitters 41 transmit ultrasonic signals to the sensed object. When the ultrasonic signals reach the sensed object, the ultrasonic signals are reflected to the ultrasonic sensor array 400 and are received by the receivers 43. The processor calculates the distance between the sensed object and the ultrasonic sensor array 400 according to a time difference between transmitting the ultrasonic signals by the transmitters 41 and receiving the ultrasonic signals by the receivers 43.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. An ultrasonic sensor comprising:
a substrate;
a first electrode coupled on the substrate;
a sensing layer coupled on the first electrode and having piezoelectric properties; and
a second electrode coupled on the sensing layer and having an electric conduction circuit formed thereon.

2. The ultrasonic sensor of claim 1, wherein the substrate comprises two spaced substrate portions.

3. The ultrasonic sensor of claim 2, wherein two spaced substrate portions are symmetric to each other.

4. The ultrasonic sensor of claim 2, wherein the first electrode comprises a first face and a second face opposite to the first face, the first face of the first electrode being coupled to the sensing layer, the second face of the first electrode being coupled to the substrate.

5. The ultrasonic sensor of claim 4, wherein the second face of the first electrode is in direct physical contact with the two substrate portions.

6. The ultrasonic sensor of claim 1, wherein the sensing layer comprises a first face and a second face opposite to the first face, the first face of the sensing layer being coupled to the first electrode, the second face of the sensing layer being coupled to the second electrode.

7. The ultrasonic sensor of claim 6, wherein the first face of the sensing layer is in direct physical contact with the first electrode.

8. The ultrasonic sensor of claim 1, wherein the substrate has a material of silicon.

9. The ultrasonic sensor of claim 1, wherein the sensing layer has a material of piezoelectric polymers.

10. The ultrasonic sensor of claim 1, wherein the sensing layer has a material of PVDF.

11. The ultrasonic sensor of claim 1, wherein the sensing layer produces inverse piezoelectric effect.

12. The ultrasonic sensor of claim 11, wherein the sensing layer produces inverse piezoelectric effect.

13. A method for manufacturing an ultrasonic sensor, comprising:
providing a base substrate;
forming a first electrode on the base substrate by PVD method;
forming a sensing layer on the first electrode by PVD method; and
forming a second electrode on the sensing layer by physical vapor deposition (PVD) method.

14. The method of claim 13, after forming a sensing layer on the first electrode by PVD method, further comprising: making the sensing layer to have piezoelectric properties by high voltage polarization.

15. The method of claim 13, after forming a second electrode on the sensing layer by PVD method, further comprising: etching the base substrate to form two substrate portions.

16. An ultrasonic sensor array comprising:
a base and a plurality of ultrasonic sensors arranged on the base, each of the ultrasonic sensors having piezoelectric properties, the plurality of ultrasonic sensors being configured to transmit and receive ultrasonic signals.

17. The ultrasonic sensor array of claim 16, wherein the plurality of ultrasonic sensors are arranged in a plurality of rows and columns on the base.

18. The ultrasonic sensor array of claim 16, wherein the plurality of ultrasonic sensors are arranged on a plurality of concentric circles on the base.

19. The ultrasonic sensor array of claim 16, wherein each of the ultrasonic sensors is configured to transmit and receive ultrasonic signals.

20. The ultrasonic sensor array of claim 16, wherein the plurality of ultrasonic sensor are divided to a plurality of receivers configured to receiving ultrasonic signals and a plurality of transmitters configured to transmit ultrasonic signals.
